(19) United States
(12) Patent Application Publication
(10) Pub. No.: US 2026/0020402 A1
(43) Pub. Date: Jan. 15, 2026

(54) DISPLAY DEVICE INCLUDING WINDOW, ELECTRONIC DEVICE INCLUDING DISPLAY DEVICE, AND METHOD FOR REPAIRING THE DISPLAY DEVICE

(71) Applicant: Samsung Display Co., Ltd., Yongin-si (KR)

(72) Inventors: YONGKWON SOH, Yongin-si (KR); GYUMDONG BAE, Yongin-si (KR); Jonghyuck KIM, Yongin-si (KR); HUN-TAE KIM, Yongin-si (KR); SOONNYUNG PARK, Yongin-si (KR)

(21) Appl. No.: 19/197,899

(22) Filed: May 2, 2025

(30) Foreign Application Priority Data
Jul. 10, 2024 (KR) 10-2024-0090816

(51) Int. Cl. H10H 29/01; H10H 29/853; H10K 59/80; H10K 71/00

(52) U.S. Cl. CPC H10H 29/0362; H10H 29/853; H10K 59/873; H10K 71/861

(57) ABSTRACT

A display device including a window, an electronic device including the display device and a method for repairing the window of the display device are provided. The display device includes a window including a protective layer, a base substrate below the protective layer, an adhesive layer between the protective layer and the base substrate, and a light blocking pattern along an edge of the protective layer and between the protective layer and the adhesive layer, and includes a display module below the window, wherein a cutting line is defined in the base substrate and the cutting line overlaps the light blocking pattern.

### CROSS-REFERENCE TO RELATED APPLICATION

The present application claims priority to and the benefit of Korean Patent Application No. 10-2024-0090816, filed on Jul. 10, 2024, in the Korean Intellectual Property Office, the entire disclosure of which is incorporated herein by reference.

### BACKGROUND

### 1. Field

Embodiments of the present disclosure relate to a display device including a window, an electronic device including the display device, and a method for repairing the window.

### 2. Description of the Related Art

Various display devices, such as televisions, mobile phones, tablet computers, and gaming consoles, have been developed.

Recently, flexible display devices including flexible display panels that may slide or fold have also been developed. Unlike rigid display devices, the flexible display devices may be folded, rolled, or bent.

Flexible display devices, which take on various shapes, offer improved portability without being restricted by the screen size, thereby enhancing user convenience. A method for repairing a window included in such flexible display devices is desired and/or required.

The above information disclosed in this Background section is intended to enhance understanding of the background of the disclosure and may contain information that does not constitute prior art.

### SUMMARY

Aspects of one or more embodiments of the present disclosure are directed toward a display device including a window that is easy to repair.

Aspects of one or more embodiments of the present disclosure are directed toward a method for repairing the window.

Additional aspects will be set forth in part in the description which follows and, in part, will be apparent from the description, or may be learned by practice of the presented embodiments of the disclosure.

one or more embodiments of the present disclosure provide a display device including a window including: a protective layer; a base substrate arranged below the protective layer; an adhesive layer arranged between the protective layer and the base substrate; and a light blocking pattern arranged along an edge of the protective layer and between the protective layer and the adhesive layer; and a display module arranged below the window, wherein a cutting line (e.g., which is provided by cutting at least a portion of the base substrate), is defined in the base substrate, and the cutting line overlaps the light blocking pattern.

In one or more embodiments, the cutting line may be a groove passing through the base substrate, and the adhesive layer overlapping the cutting line may be exposed through the cutting line.

In one or more embodiments, the cutting line may be a groove passing partially through the base substrate in a direction from a bottom surface toward a top surface of the base substrate.

In one or more embodiments, the base substrate may extend along first and second directions intersecting each other, and the cutting line may extend in an oblique direction with respect to the first and second directions.

In one or more embodiments, the base substrate may have long sides and short sides, the long sides extending in directions that intersect the short sides, and corners at intersections of the long sides and the short sides, and the corners may have a set or predetermined curvature.

In one or more embodiments, the cutting line may overlap any one of the corners.

In one or more embodiments, the cutting line may include a plurality of cutting lines, and each of the cutting lines may overlap any one of the corners.

In one or more embodiments, a side surface of the protective layer, a side surface of the adhesive layer, and a side surface of the base substrate may be aligned with each other in a cross-section.

In one or more embodiments, the cutting line may not be visible from the outside on a plane (e.g., in a plan view).

In one or more embodiments, the base substrate may include polyethylene terephthalate (PET).

In one or more embodiments, the adhesive layer may include at least one of a pressure-sensitive adhesive (PSA), an optically clear adhesive (OCA), or an optically clear resin (OCR).

In one or more embodiments, the protective layer may include at least one of a fingerprint-resistant coating agent, a hard coating agent, or an anti-static agent.

In one or more embodiments of the present disclosure, a display device includes: a window including: a protective layer; a base substrate arranged below the protective layer; an adhesive layer arranged between the protective layer and the base substrate; and a light blocking pattern arranged along an edge of the protective layer and between the protective layer and the adhesive layer; and a display module arranged below the window, wherein a groove is defined in the base substrate at corners of the base substrate overlapping the light blocking pattern.

In one or more embodiments of the present disclosure, a method for repairing a window includes: coupling a base substrate, an adhesive layer, a light blocking pattern, and a protective layer to each other to form a window assembly; cutting the base substrate, the adhesive layer, and the protective layer along an outer portion of the light blocking pattern to form the window; forming a cutting line in a portion of the base substrate that overlaps the light blocking pattern; coupling the window to a display module; and separating the base substrate from the adhesive layer, the light blocking pattern, and the protective layer by attaching a tape to the protective layer and using (utilizing) the cutting line as a boundary.

In one or more embodiments, the method may further include re-working the window by coupling a new adhesive layer, a new light blocking pattern and a new protective layer to the protective layer, after the separating of the base substrate from the adhesive layer, the light blocking pattern, and the protective layer.

In one or more embodiments, after the re-working of the window, side surfaces of the new adhesive layer and the protective layer may protrude further outward than a side surface of the base substrate.

In one or more embodiments, in the separating of the base substrate from the adhesive layer, the light blocking pattern, and the protective layer, an outer portion of the base substrate with respect to the cutting line may adhere to the adhesive layer and may be removed from a remaining portion of the base substrate.

In one or more embodiments, in the forming of the cutting line, the cutting line may pass through the base substrate to expose the adhesive layer.

In one or more embodiments, the forming of the window may further include attaching a release film to a lower portion of the base substrate, and in the forming of the cutting line, the release film is penetrated together with the base substrate.

In one or more embodiments, the method may further include removing the release film before the coupling of the window to the display module.

One or more embodiments of the present disclosure may include an electronic device including the aforementioned display device.

one or more embodiments, the electronic device may include a smartphone, a tablet, a car navigation system, a gaming console, or a wearable device

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1A is a perspective view of an electronic apparatus according to one or more embodiments of the present disclosure;

FIG. 1B is a perspective view of the electronic apparatus according to one or more embodiments of the present disclosure;

FIG. 1C is a plan view of the electronic apparatus according to one or more embodiments of the present disclosure;

FIG. 1D is a perspective view of the electronic apparatus according to one or more embodiments of the present disclosure;

FIG. 2A is a perspective view of an electronic apparatus according to one or more embodiments of the present disclosure;

FIG. 2B is a perspective view of the electronic apparatus according to one or more embodiments of the present disclosure;

FIG. 2C is a perspective view of the electronic apparatus according to one or more embodiments of the present disclosure;

FIG. 3 is an exploded perspective view of an electronic apparatus according to one or more embodiments of the present disclosure;

FIG. 4 is a cross-sectional view taken along the line I-I′ of FIG. 3, according to one or more embodiments of the present disclosure;

FIG. 5 is a plan view of a display panel according to one or more embodiments of the present disclosure;

FIG. 6A is a cross-sectional view of a display device according to one or more embodiments of the present disclosure;

FIG. 6B is a cross-sectional view of a display device according to one or more embodiments of the present disclosure;

FIG. 7 is a plan view of a display device according to one or more embodiments of the present disclosure;

FIG. 8 is a plan view of a display device according to one or more embodiments of the present disclosure;

FIG. 9A is a plan view of a display device according to one or more embodiments of the present disclosure;

FIG. 9B is a cross-sectional view taken along the line II-II′ of FIG. 9A, according to one or more embodiments of the present disclosure; and

FIGS. 10A to 10H are views illustrating methods for repairing a display window according to embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on,” “connected to,” or “coupled to” another element, it can be directly on, connected to, or coupled to the other element, or one or more intervening elements may be present. In contrast, when an element or layer is referred to as being “directly on,” “directly connected to”, “directly coupled to”, or “immediately adjacent to” another element or layer, there are no intervening elements or layers present. In addition, it will also be understood that when an element is referred to as being “between” two elements, it can be the only element between the two elements, or one or more intervening elements may also be present. Unless otherwise noted, like reference numerals denote like elements throughout the attached drawings and the written description, and thus, duplicative descriptions thereof may not be provided. Thicknesses, ratios, dimensions of elements may be exaggerated for effective description of the technical contents. For example, in the drawings, the relative sizes of elements, layers, and regions may be exaggerated for clarity.

As used herein, the term “and/or” includes any and all combinations of one or more of the associated listed items.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the singular forms, “a”, “an” and “the” are intended to include the plural forms as well, unless the context clearly indicates otherwise.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification and should not be interpreted in an idealized or overly formal sense, unless expressly so defined herein.

Further, the use of “may” when describing embodiments of the present disclosure refers to “one or more embodiments of the present disclosure.”

Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively.

In the context of the present disclosure and unless otherwise defined, a plan view is an orthographic projection of a three-dimensional object from the position of a horizontal plane through the object. That is, it is a top-down view, showing the layout and spatial relationships of various elements within the object or structure. A plan view based on the direction DR3 refers to a top-down view of the display panel, as if looking directly down onto the surface from above. In this context, DR3 is the direction perpendicular or normal to the plane defined by the first direction DR1 and the second direction DR2. This refers to that in a plan view, the arrangement of sub-pixels, pads, and other components as they are laid out on the substrate can be seen, without any perspective distortion.

Hereinafter, the present disclosure will be explained in more detail with reference to the accompanying drawings.

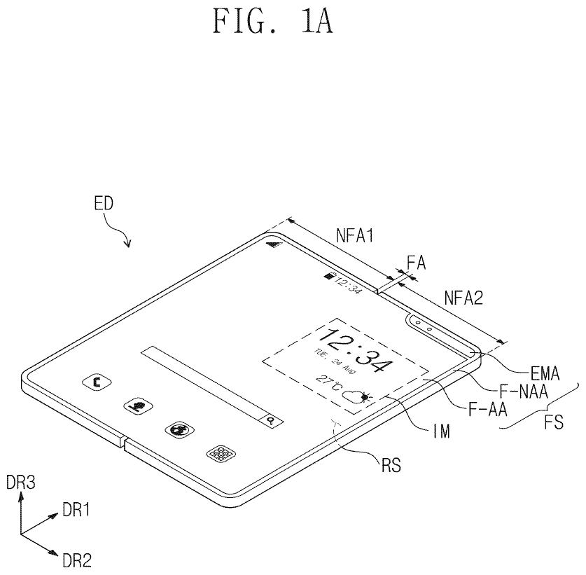

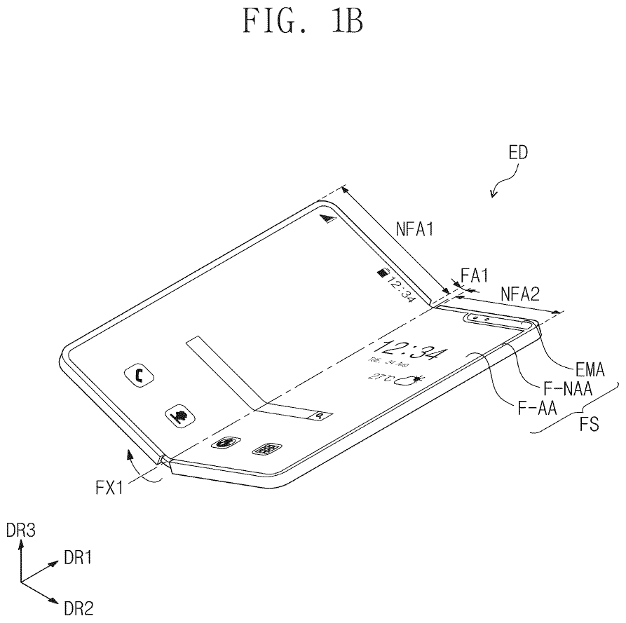

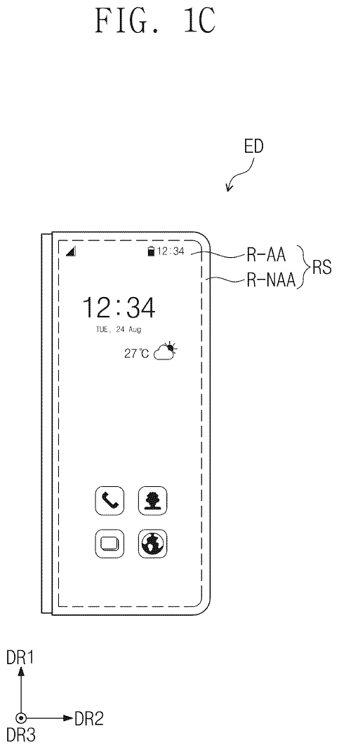

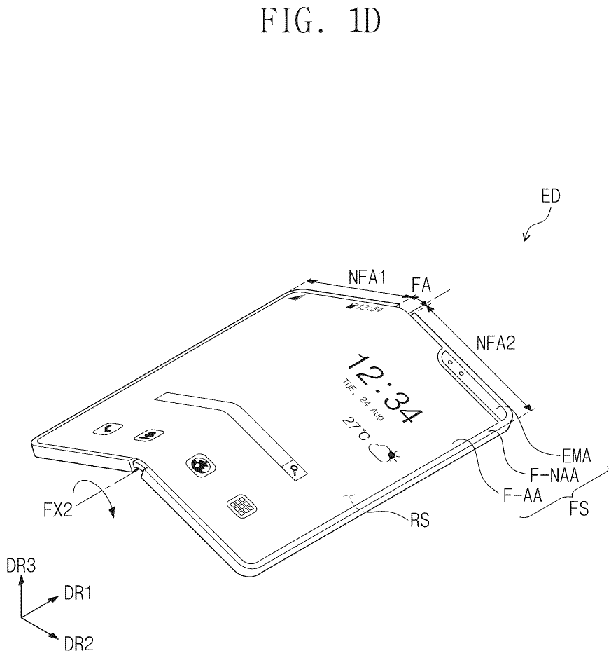

FIG. 1A is a perspective view of an electronic apparatus according to one or more embodiments of the present disclosure. FIG. 1B is a perspective view of the electronic apparatus according to one or more embodiments of the present disclosure. FIG. 1C is a plan view of the electronic apparatus according to one or more embodiments of the present disclosure. FIG. 1D is a perspective view of the electronic apparatus according to one or more embodiments of the present disclosure

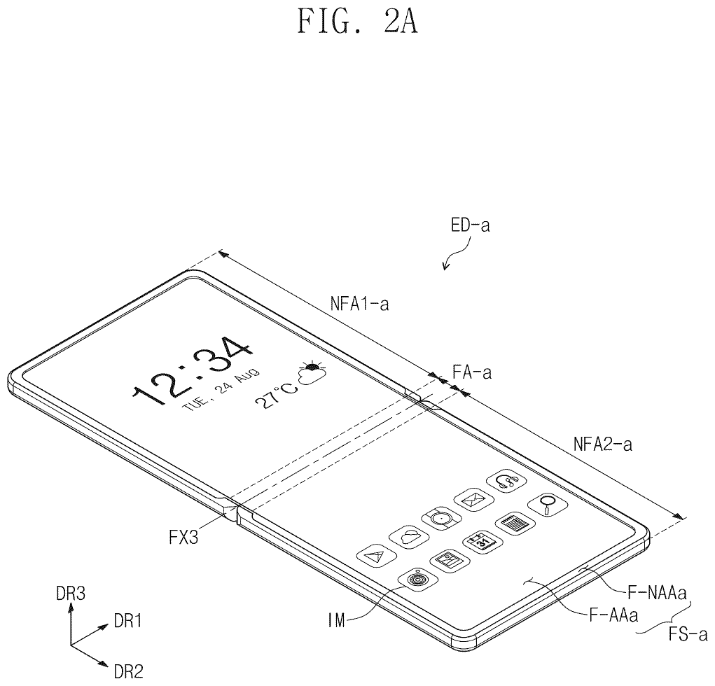

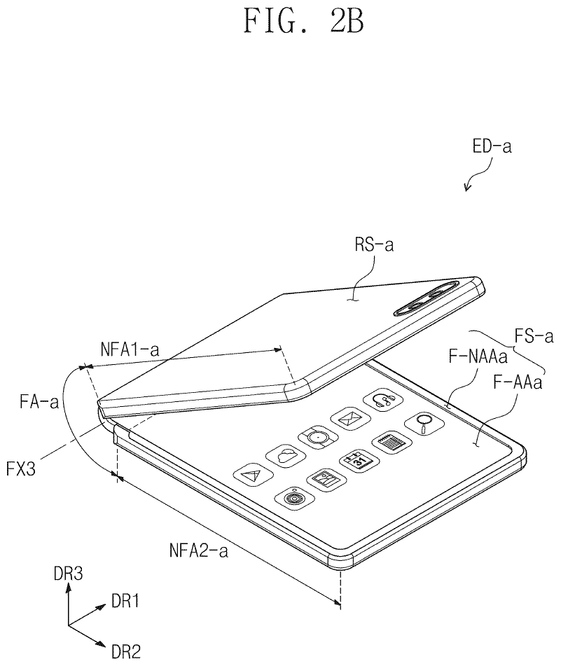

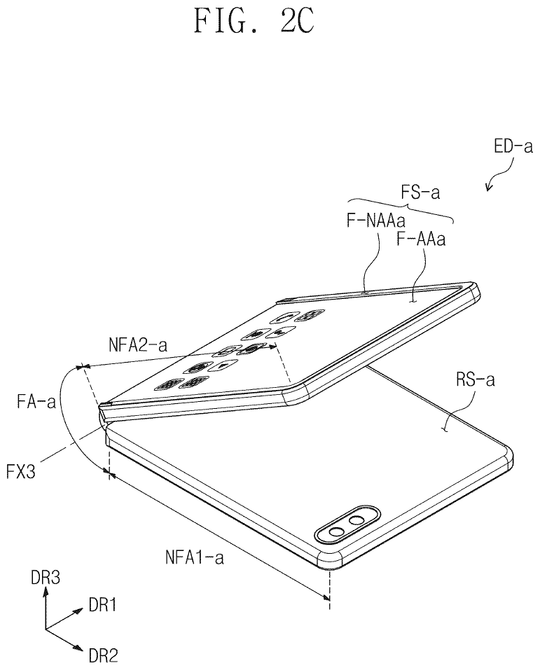

FIG. 1A is a perspective view illustrating a state in which the electronic apparatus ED is opened according to one or more embodiments of the present disclosure. The electronic apparatus ED according to one or more embodiments may be a device that is activated according to an electrical signal. For example, the electronic apparatus ED may be a smartphone, a tablet, a car navigation system, a gaming console, or a wearable device, but the present disclosure is not limited thereto. FIGS. 1A to 2C illustrate examples of foldable electronic apparatuses ED and ED-a. Each of the foldable electronic apparatuses ED and ED-a may be a mobile phone.

The electronic apparatus ED may include a first display surface FS that is defined by a first direction DR1 and a second direction DR2 intersecting the first direction DR1. The electronic apparatus ED may provide an image IM to the user through the first display surface FS. The electronic apparatus ED may display the image IM in a third direction DR3 through the first surface FS, which is parallel to both the first and second directions DR1 and DR2.

In the present disclosure, the first direction DR1 and the second direction DR2 are orthogonal to each other, and the third direction DR3 may be a normal line to a plane defined by the first and second directions DR1 and DR2. A direction of thickness (hereinafter, referred to as a “thickness direction”) of the electronic apparatus ED may be parallel to the third direction DR3. A front surface (or a top surface) and a rear surface (or a bottom surface) may be opposite each other in the third direction DR3, and a normal line of each of the front surface (or the top surface) and the rear surface (or the bottom surface) may be parallel. The front surface (or top surface) may refer to a surface that is close to the first display surface FS, while the rear surface (bottom surface) may refer to a surface spaced and/or apart (e.g., spaced apart or separated) from the first display surface FS. Also, the rear surface (bottom surface) may refer to a surface that is close to a second display surface RS that will be described in more detail later. An upper side (or an upper portion) may refer to a side or portion adjacent to the first display surface FS, while a lower side (or a lower portion) may refer to a side or portion spaced or away from the first display surface FS.

A cross-section of the components may refer to a surface parallel to the third direction DR3, which is the thickness direction, while a plane (or a plan view) may refer to a surface normal (e.g., perpendicular) to the third direction DR3. The plane may refer to a surface that is defined by the first and second directions DR1 and DR2.

The electronic apparatus ED may sense an external input applied from the outside. The external input may include a one or more suitable types (kinds) of inputs which are applied from the outside of the electronic apparatus ED. For example, the external input may include not only contact from a portion of the user's body, such as a hand, but also input (e.g., hovering) applied by being in proximity to or at a set or predetermined distance from the electronic apparatus ED. Also, the external input may include one or more suitable types (kinds) of inputs, such as force, pressure, temperature, or light.

The electronic apparatus ED may include the first display surface FS and the second display surface RS. The first display surface FS may include a first active area F-AA, a first peripheral area F-NAA, and an electronic module area EMA. The second display surface RS may be defined as a surface which opposes at least a portion of the first display surface FS. For example, the second display surface RS may be defined as a portion of the rear surface of the electronic apparatus ED.

The first active area F-AA may be an area that is activated according to an electrical signal. The first active area F-AA may be an area on which the image is displayed, and one or more suitable types (kinds) of external inputs are sensed.

The first peripheral area F-NAA may be an area on which the image IM is not displayed. The first peripheral area F-NAA may be adjacent to the first active area F-AA. The first peripheral area F-NAA may have a set or predetermined color. The first peripheral area F-NAA may be around (e.g., surround) the first active area F-AA. Accordingly, a shape of the first active area F-AA may be substantially defined by the first peripheral area F-NAA. However, this is only an example, and the first peripheral area F-NAA may be arranged adjacent to only one or more sides of the first active area F-AA or may not be provided.

One or more suitable electronic modules may be arranged on (in) the electronic module area EMA. For example, the electronic module may include at least one of a camera, a speaker, a light sensor, and/or a thermal sensor. The electronic module area EMA may sense an external object received through the display surfaces FS and RS or provide a sound signal, such as voice, to the outside through the display surfaces FS and RS. The electronic module may include a plurality of components and not limited to any one embodiment.

The electronic module area EMA may be surrounded by the first peripheral area F-NAA. However, this is only an example, and the electronic module area EMA is not limited to any one embodiment. For example, the electronic module area EMA may be surrounded by the first active area F-AA and the first peripheral area F-NAA and be arranged in the first active area F-AA.

The electronic apparatus ED according to one or more embodiments may be divided into at least one folding area FA and a plurality of non-folding areas NFA1 and NFA2 extending from the folding area FA. For example, the first non-folding area NFA1, the folding area FA and the second non-folding area NFA2 may be defined along the second direction DR2. The electronic apparatus ED may be divided into the first non-folding area NFA1 and the second non-folding area NFA2, which are spaced and/or apart (e.g., spaced apart or separated) from each other in the second direction DR2, with the folding area FA therebetween. For example, the non-folding area NFA1 may be arranged on one side of the folding area FA in the second direction, while the second non-folding area NFA2 may be arranged on the other side of the folding area FA.

FIG. 1A shows the electronic apparatus ED including one folding area FA according to one or more embodiments, but the present disclosure is not limited thereto. For example, a plurality of folding areas may be defined on the electronic apparatus ED. For example, the electronic apparatus according to one or more embodiments may include two or more folding areas and three or more non-folding areas arranged with each folding area therebetween.

FIG. 1B is a perspective view illustrating a folding operation of the electronic apparatus ED according to one or more embodiments. FIG. 1C is a plan view of a state in which the electronic apparatus ED is folded according to one or more embodiments. FIG. 1D is a perspective view illustrating a folding operation of the electronic apparatus ED according to one or more embodiments.

Referring to FIG. 1B, the electronic apparatus ED according to one or more embodiments may be folded about a first folding axis FX1, which extends in the first direction DR1. When the electronic apparatus ED is in a folded state, the folding area FA may have a set or predetermined curvature and radius of curvature. The electronic apparatus may be folded about the first folding axis such that the first non-folding area and the second non-folding area face each other and may be deformed into an in-folding state, preventing or reducing first display surface FS from being exposed to the outside.

Referring to FIG. 1C, in the in-folded state of the electronic apparatus according to one or more embodiments, the second display surface may be visible to the user. Here, the second surface RS may include a second active area R-AA on which the image is displayed. The second active area R-AA may be an area that is activated according to an electrical signal. The second active area R-AA may be an area on which the image is displayed, and at which one or more suitable types (kinds) of external inputs are sensed.

Also, the second display surface RS may include a second peripheral area R-NAA. The second peripheral area R-NAA may be adjacent to the second active area R-AA. The second peripheral area R-NAA may have a set or predetermined color. The second peripheral area R-NAA may be around (e.g., surround) the second active area R-AA. Also, in one or more embodiments, the electronic apparatus ED may further include an electronic module area at which the second display surface RS includes electronic modules including one or more suitable components.

According to one or more embodiments, in a state in which the electronic apparatus ED is in-folded, a distance between the first non-folding area NFA1 and the second non-folding area NFA2 may be less than a radius of a circle defined by the radius of curvature of the folding area FA. Here, the folding area may be folded into a dumbbell shape, and the distance between the first non-folding area and the second non-folding area may become even closer. Therefore, a slimmer electronic apparatus may be provided in the folded state.

Referring to FIG. 1D, the electronic apparatus ED according to one or more embodiments may be folded about the second folding axis FX2, which extends in the first direction DR1. The electronic apparatus may be folded about the second folding axis FX2 and deformed into an out-folding state so that the first display surface FS is exposed to the outside. In one or more embodiments, the electronic apparatus ED may be configured such that in-folding or out-folding operations are alternately repeated from the unfolded state, but the present disclosure is not limited thereto.

FIGS. 1A through 1D illustrate folding based on one folding axis FX1 or FX2 as an example, but the number of folding axes and the corresponding number of non-folding areas are not limited thereto. For example, the device may be folded about a plurality of folding axes, so that portions of both the first display surface FS and the second display surface RS face each other. Additionally, although the first and second folding axes FX1, FX2 are shown as being parallel to the long side of the electronic apparatus ED, the present disclosure is not limited thereto, and the first and second folding axes FX1, FX2 may be parallel to the short side of the electronic apparatus ED.

In the electronic apparatus ED, the first non-folding area NFA1 and the second non-folding area NFA2 may be defined as portions having display surfaces FS and RS parallel to the plane defined by the first direction DR1 and the second direction DR2, as shown in FIG. 1C. The folding area FA may be defined as an area between the first non-folding area NFA1 and the second non-folding area NFA2. The folding area FA may include a curved surface portion that may be bent to have a set or predetermined curvature in the folded state.

FIG. 2A is a perspective view of an electronic apparatus according to one or more embodiments of the present disclosure. FIG. 2B is a perspective view of the electronic apparatus according to one or more embodiments of the present disclosure. FIG. 2C is a perspective view of the electronic apparatus according to one or more embodiments of the present disclosure.

FIGS. 2A to 2C are perspective views of an electronic apparatus ED-a according to other embodiments of the present disclosure. FIG. 2A is a perspective view illustrating an unfolded state of the electronic apparatus ED-a. FIGS. 2B and 2C are each a perspective view illustrating a folding operation of the electronic apparatus ED-a. FIG. 2B is a perspective view illustrating an in-folding operation of the electronic apparatus ED-a shown in FIG. 2A. FIG. 2C is a perspective view illustrating an out-folding operation of the electronic apparatus ED-a shown in FIG. 2A. FIG. 2A may be a drawing of the electronic apparatus ED-a according to one or more embodiments.

Referring to FIG. 2A, the electronic apparatus ED-a may be folded about a third folding axis FX3, which extends along a first direction DR1. A direction in which the third folding axis FX3 extends may be parallel to an extension direction of a short side of the electronic apparatus ED-a.

The electronic apparatus ED-a may be divided into a folding area FA-a, a first non-folding area NFA1-a adjacent to one side of the folding area FA-a, and a second non-folding area NFA2-a adjacent to the other side of the folding area FA-a. The first non-folding area NFA1-a and the second non-folding area NFA2-a may be spaced and/or apart (e.g., spaced apart or separated) from each other with the folding area FA-a therebetween.

The folding area FA-a may be an area that folds about the third folding axis FX3. In the folded state of the electronic apparatus ED-a, the folding area FA-a may have a set or predetermined curvature and radius of curvature. The first non-folding area NFA1-a and the second non-folding area NFA2-a may face each other, and the electronic apparatus ED-a may be in-folded so that the display surface FS is not exposed to the outside.

Referring to FIG. 2A, in one or more embodiments, the electronic apparatus ED-a may include a display surface FS-a, which is visible to the user in an opened state (i.e., not folded). As described with reference to FIGS. 1A to 1D, the display surface FS-a of the electronic apparatus ED-a may include an active area F-AAa and a peripheral area F-NAAa. The active area F-AAa may be an area on which an image IM is displayed, and at which one or more suitable types (kinds) of external inputs are sensed.

Referring to FIG. 2B, in the in-folded state of the electronic apparatus ED-a according to one or more embodiments, a rear surface RS-a may be visible to the user. For example, the rear surface RS-a may function as a second display surface for displaying an image or video. Additionally, an electronic module area on which an electronic module including one or more suitable components is arranged, may be arranged on the rear surface RS-a. According to one or more embodiments, the rear surface RS-a of the electronic apparatus ED-a may further include an active area on which the image is displayed.

Referring to FIG. 2C, the electronic apparatus ED-a may be folded about the third folding axis FX3 and be deformed into an out-folding state in which one area of the rear surface RS-a overlaps the first non-folding area NFA1-a and the other area of the rear surface RS-a overlaps the second non-folding area NFA2-a to face each other.

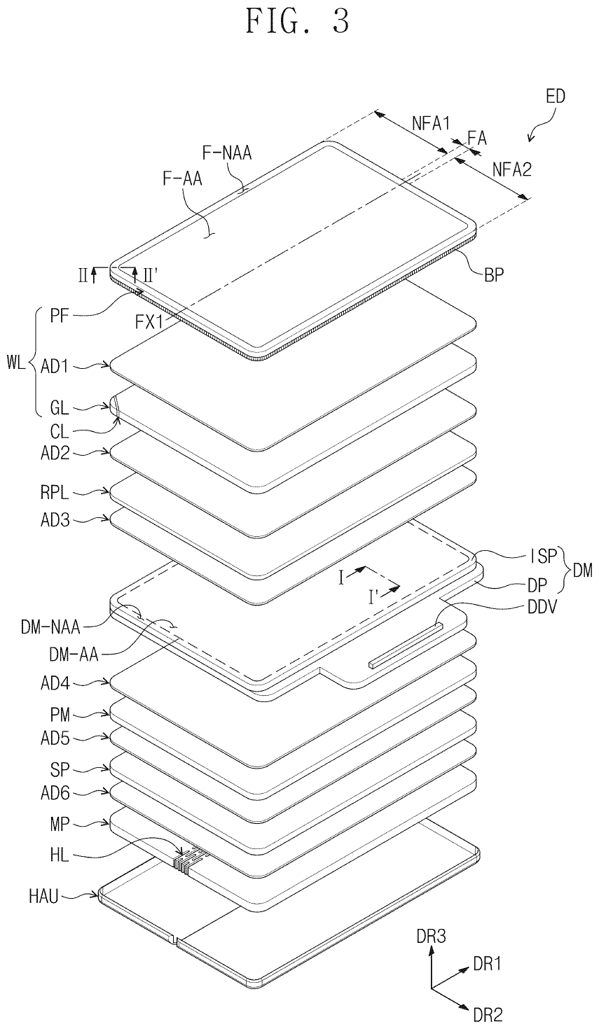

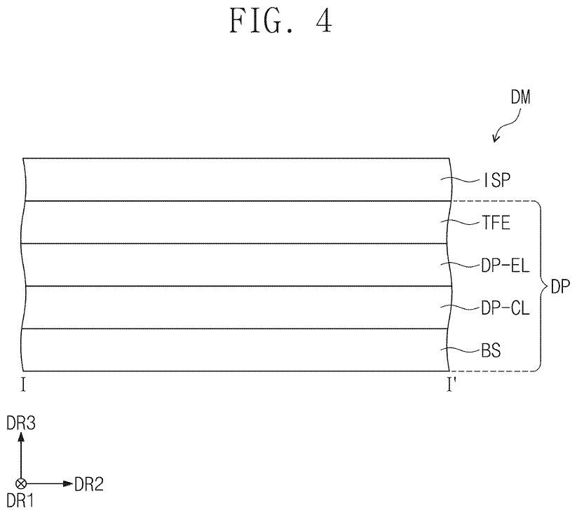

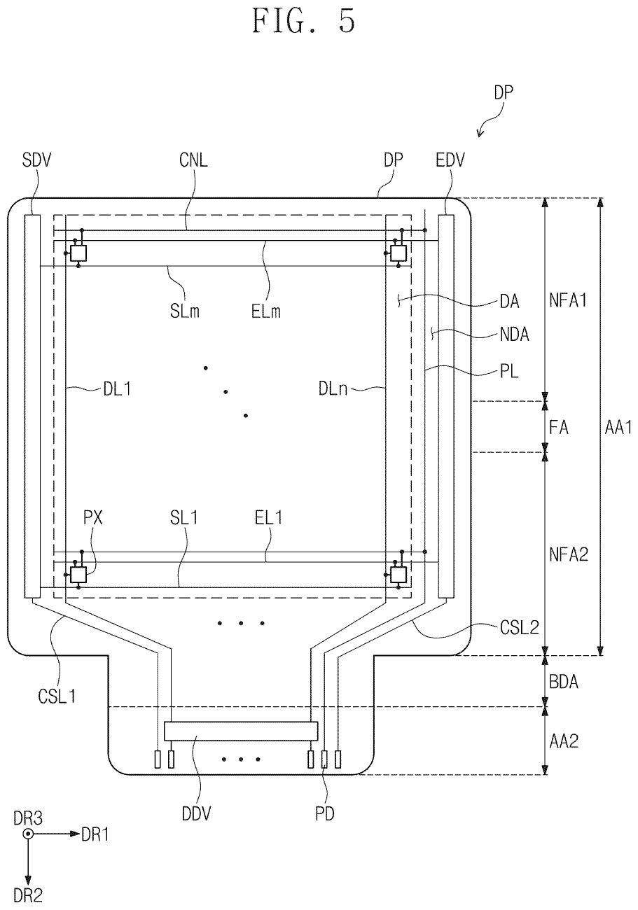

FIG. 3 is an exploded perspective view of an electronic apparatus device according to one or more embodiments of the present disclosure. FIG. 4 is a cross-sectional view taken along the line I-I′ of FIG. 3, according to one or more embodiments of the present disclosure. FIG. 5 is a plan view of a display panel according to one or more embodiments of the present disclosure. The features described in more detail below regarding the electronic apparatus ED may be applied to the electronic apparatus ED-a described in FIGS. 2A to 2C.

Referring to FIG. 3, an electronic apparatus ED may include a window WL, a display module DM, an optical layer RPL, a lower film PM, a support plate SP, a lower plate MP, and a housing HAU. In the present disclosure, a state in which the window WL, the optical layer RPL, and the display module DM are coupled to each other may be defined as a “display device.”

The housing HAU may be coupled to the window WL and define the exterior of the electronic apparatus ED. The housing HAU may include a material with relatively high rigidity. For example, the housing HAU may include a plurality of frames and/or support plates made of glass, plastic, or metal. The housing HAU may provide a set or predetermined accommodation space. The display module DM may be accommodated within the accommodation space and protected from external impacts. According to one or more embodiments, the housing HAU that overlaps a folding area FA may further include a hinge structure and/or the like to guide a folding operation of the electronic apparatus ED.

The display module DM may be arranged below the optical layer RPL. The display module DM may be activated according to an electrical signal. The display module DM may be activated to display the image IM (see, e.g., FIG. 1A) on (in) the active area F-AA (see, e.g., FIG. 1A) of the electronic apparatus ED. A display area DM-AA and a non-display area DM-NAA may be defined in the display module DM. The display area DM-AA may be an area that is activated according to an electrical signal. The non-display area DM-NAA may be an area arranged adjacent to at least one side of the display area DM-AA. In the non-display area DM-NAA, a circuit and/or wiring for driving the display area DM-AA may be arranged.

The optical layer RPL may be arranged between the display module DM and the window WL. The optical layer RPL may be an anti-reflective layer that reduces the reflectance of external light incident from outside of the display module DM. The optical layer RPL may be arranged on the display module DM through a sequential process. The optical layer RPL may include a polarizing plate and/or a color filter layer. For example, the optical layer RPL may include at least one of a retarder, polarizer, polarizing film, and/or a polarizing filter. In one or more embodiments, the optical layer RPL may include a plurality of color filters arranged in a set or predetermined array and a black matrix adjacent to the color filters.

The image IM (see, e.g., FIG. 1A) generated by the display module DM may pass through the window WL and be provided to the user. The window WL may include a polymer substrate or a glass substrate.

The window WL according to one or more embodiments may include a protective layer PF and a base substrate GL. The protective layer PF and the base substrate GL may include an optically transparent insulating material. In one or more embodiments, the base substrate GL may include polyethylene terephthalate (PET).

The protective layer PF may be arranged on the base substrate GL. The protective layer PF may be a functional layer that protects a top surface of the base substrate GL. The protective layer PF may include a polymer film.

The base substrate GL according to one or more embodiments of the present disclosure may have a cutting line CL defined by removing at least a portion of the base substrate GL. The cutting line CL may allow for the easy separation of components included in the window WL during a window repair process, which will be described in more detail later. Further explanation regarding the role of the cutting line CL will be provided in more detail later.

The protective layer PF may include a fingerprint-resistant coating agent, a hard coating agent, an anti-static agent, and/or the like. According to one or more embodiments, a light blocking pattern BP may be arranged between a first adhesive layer AD1 and the protective layer PF. The light blocking pattern BP may be provided by printing or coating on a portion adjacent to an edge of a bottom surface of the protective layer PF. The light blocking pattern BP is not limited to any particular material, as long as it absorbs light.

A boundary between the first active area F-AA and F-AAa and the first peripheral area F-NAA and F-NAAa, of the electronic apparatus ED may be defined by the light blocking pattern BP. An area in which the light blocking pattern BP is arranged may be defined as first peripheral areas F-NAA and F-NAAa.

A lower film PM may protect a lower portion of a display panel DP. The lower film PM my include a flexible plastic material. For example, the lower film PM may include polyethylene terephthalate.

The support plate SP may be arranged below the display panel DP. A portion of the support plate SP according to one or more embodiments of the present disclosure may be bent to absorb impacts applied between components arranged on the support plate SP and the housing HAU. Also, the support plate SP may prevent or reduce the likelihood of (e.g., protect from) foreign substances entering the components arranged on the support plate SP.

The lower plate MP may be arranged below the support plate SP. The lower plate MP may include a plurality of holes HL that overlaps the folding area and that passes through the lower plate MP to facilitate a folding operation of the electronic apparatus ED. The lower plate MP may include metal. For example, the lower plate MP may include either aluminum (Al) or molybdenum (Mo). However, the present disclosure is not limited thereto, and the lower plate MP may include a matrix with fillers and woven fiber lines arranged inside the matrix. The fiber lines may be arranged in a fabric shape within the matrix.

The fiber lines may include reinforced fiber composites. The reinforced fiber composite may be one of carbon fiber-reinforced plastics (CFRP) or glass fiber-reinforced plastic (GFRP). The diameter of a single fiber included in a fiber line may range from about 3 μm to about 10 μm.

The matrix according to one or more embodiments may include at least one of epoxy, polyester, polyamides, polycarbonates, polypropylene, polybutylene, or vinyl ester.

The matrix may include a filler. The filler may include at least one of silica, barium sulphate, sintered talc, barium titanate, titanium oxide, clay, alumina, mica, boehmite, zinc borate, or zinc stannate.

The electronic apparatus ED according to one or more embodiments may further include at least one of a cushioning layer and/or a shielding layer. The cushioning layer may prevent or reduce the likelihood of plastic deformation of the lower plate MP caused by pressing due to external impacts and forces. The cushioning layer may include elastomers such as sponge, foam, or urethane resin. Additionally, the cushioning layer may include at least one of acrylic polymers, urethane polymers, silicone polymers, or imide polymers. The shielding layer may be an electromagnetic wave shielding layer or a heat-dissipating layer.

The electronic apparatus ED according to one or more embodiments may further include first to sixth adhesive layers AD1 to AD6. The first adhesive layer AD1 may be arranged between the base substrate GL and the protective layer PF. The second adhesive layer AD2 may be arranged between the optical layer RPL and the base substrate GL. The third adhesive layer AD3 may be arranged between the display module DM and the optical layer RPL. The fourth adhesive layer AD4 may be arranged between the lower film PM and the display module DM. The fifth adhesive layer AD5 may be arranged between the support plate SP and the lower film PM. The sixth adhesive layer AD6 may be arranged between the lower plate MP and the support plate SP.

Each of the first to sixth adhesive layers AD1 to AD6, and the adhesive layers described in more detail later, may include an adhesive such as a pressure-sensitive adhesive (PSA), optically clear adhesive (OCA), or optically clear resin (OCR), but the present disclosure is not limited thereto. In the electronic apparatus ED according to one or more embodiments, at least one of the first to sixth adhesive layers AD1 to AD6 may not be provided.

Further, FIG. 3 is an example of a stacked structure of a foldable electronic apparatus ED, and the window WL according to one or more embodiments of the present disclosure may be applied regardless of the components arranged below the window WL and the display module DM.

Referring to FIG. 4, the display module DM may include a display panel DP and an input sensing layer ISP arranged on the display panel DP. The display panel DP may be a component that substantially generates the image. The display panel DP may be a self-emissive display panel. For example, the display panel DP may be an organic light-emitting display panel, an inorganic light-emitting display panel, a micro-LED display panel, a micro-OLED display panel, or a nano-LED display panel.

The display panel DP may include a base layer BS, a circuit layer DP-CL, a display element layer DP-EL, and an encapsulation layer TFE, which are sequentially stacked. In one or more embodiments, a functional layer may further be arranged between any two adjacent layers of the base layer BS, the circuit layer DP-CL, the display element layer DP-EL, and the encapsulation layer TFE.

The base layer BS may provide a base surface on which the circuit layer DP-CL is arranged. The base layer BS may be a flexible substrate capable of bending, folding, or rolling. The base layer BS may be a glass substrate, a metal substrate, or a polymer substrate. However, the present disclosure is not limited thereto, and the base layer BS may include an inorganic layer, an organic layer, or a composite material layer.

The base layer BS may include a single layer or multiple layers. For example, the base layer BS may include a first synthetic resin layer, a multilayer or single-layer inorganic layer, and a second synthetic resin layer arranged on the multilayer or single-layer inorganic layer. Each of the first synthetic resin layer and the second synthetic resin layer may include polyimide resin. Additionally, each of the first synthetic resin layer and the second synthetic resin layer may include at least one of acrylic resin, methacrylic resin, polyisoprene resin, vinyl resin, epoxy resin, urethane resin, cellulose resin, siloxane resin, polyamide resin, or perylene resin.

In this specification, a “˜˜ based” resin refers to a resin that contains the functional group of “˜˜.”

The circuit layer DP-CL may be arranged on the base layer BS. The circuit layer DP-CL may include an insulating layer, a semiconductor pattern, a conductive pattern, and a signal line, and/or the like. The display element layer DP-EL may be arranged on the circuit layer DP-CL. The display element layer DP-EL may include a light-emitting element. For example, the light-emitting element may include organic light-emitting materials, inorganic light-emitting materials, organic-inorganic light-emitting materials, quantum dots, quantum rods, micro-LEDs, or nano-LEDs.

The encapsulation layer TFE may be arranged on the display element layer DP-EL. The encapsulation layer TFE may protect the display element layer DP-EL from foreign substances such as moisture, oxygen, and/or dust particles. The encapsulation layer TFE may include at least one inorganic layer. For example, the encapsulation layer TFE may include an inorganic layer, an organic layer, and an inorganic layer that are sequentially stacked.

The input sensing layer ISP may be arranged on the display panel DP. The input sensing layer ISP may be directly arranged on the encapsulation layer TFE. In one or more embodiments, an adhesive member may be arranged between the input sensing layer ISP and the display panel DP.

In this specification, when one component is said to be “directly arranged” on another, no third component is placed between them. For example, “directly arranged” refers to that the two components are in contact with each other.

The input sensing layer ISP may sense external input, convert it into a set or predetermined input signal, and provide the input signal to the display panel DP. For example, the input sensing layer ISP may be a touch sensing layer that senses touch. The input sensing layer ISP may recognize direct touch by the user, indirect touch by the user, direct touch by an object, or indirect touch by an object.

The input sensing layer ISP may sense at least one of the position of the touch and/or the intensity (pressure) of the touch applied from the outside. The input sensing layer ISP may have one or more suitable structures or be composed of one or more suitable materials and is not limited to any one or more embodiments. For example, the input sensing layer ISP may sense external input using a capacitive method. The display panel DP may receive an input signal from the input sensing layer ISP and generate an image corresponding to the input signal.

Referring to FIG. 5, the display panel DP may include pixels PX, a scan driver SDV, a data driver DDV, and an emission driver EDV.

The display panel DP may include a first area AA1, a second area AA2, and a bending area BDA between the first area AA1 and the second area AA2. The bending area BDA may extend along the first direction DR1, and the first area AA1, the bending area BDA, and the second area AA2 may be arranged along a second direction DR2. The bending area BDA may be bent along a bending axis extending in a first direction DR1, such that the second area AA2 overlaps a bottom surface of the first area AA1. According to one or more embodiments, the bending area BDA and the second area AA2 may each have a width in the first direction DR1, which is less than that of the first area AA1 in the first direction DR1. Thus, the bending area BA may be relatively easily bent toward the bottom surface of the first area AA1.

The first area AA1 may include a display area DA and a peripheral non-display area NDA adjacent to the display area DA. The non-display area NDA may be around (e.g., surround) the display area DA. The display area DA is an area in which the image is displayed, while the non-display area NDA may be an area in which the image is not displayed. The second area AA2 and the bending area BDA may be an area in which the image is not displayed.

The first area AA1 may include a first non-folding area NFA1, a second non-folding area NFA2, and a folding area FA between the first non-folding area NFA1 and the second non-folding area NFA2, arranged along the second direction DR2. The first and second non-folding areas NFA1, NFA2, and the folding area FA may correspond to the first and second non-folding areas NFA1, NFA2, and the folding area FA of the electronic apparatus ED shown in FIG. 1A.

The first area AA1 may be bent and folded along the above-described folding axes. For example, because the folding area FA of the first area AA1 is folded along the above-described folding axes, the display panel DP may be folded.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, a power line PL, a plurality of connection lines CNL, and a plurality of pads PD. The alphabet letter, m and n are a natural number. The pixels PX may be arranged in the display area DA and be connected to the scan lines SL1 to SLm, the data lines DL1 to DLn, and the light-emission lines EL1 to ELm.

The scan driver SDV and the light-emission emission driver may be arranged in the non-display area NDA. The scan driver SDV and the emission driver EDV may be arranged in the non-display area NDA adjacent to opposite sides of the first area AA1 in the first direction DR1, respectively. The data driver may be arranged in the second area AA2. The data driver DDV may be manufactured in the type (kind) of an integrated circuit chip and mounted on the second area AA2.

The scan lines SL1 to SLm may extend in the first direction DR1 and be connected to the scan driver SDV. The data lines DL1 to DLn may extend in the second direction DR2 and be connected to the data driver DDV via the bending area BDA. The data driver DDV may be connected to the pixels PX through the data lines DL1 to DLn. The emission lines EL1 to ELm may extend in the first direction DR1 and be connected to the emission driver EDV.

The power line PL may extend in the second direction DR2 and be arranged in the non-display area NDA. The power line PL may be arranged between the display area DA and the emission driver EDV. The power line PL may extend to the second area AA2 via the bending area BDA. The power line PL may extend toward a lower end of the second area AA2 when viewed on a plane (e.g., in a plan view). The power line PL may receive a driving voltage.

The connection lines CNL may extend in the first direction DR1 and be arranged in the second direction DR2. The connection lines CNL may be connected to the power line PL and the pixels PX. The driving voltage may be applied to the pixels PX through the power line PL and the connection lines CNL connected to each other.

The first control line CSL1 may be connected to the scan driver SDV and extend toward the lower end of the second area AA2 via the bending area BDA. The second control line CSL2 may be connected to the emission driver EDV and extend toward the bottom end of the second area AA2 via the bending area BDA. The data driver DDV may be arranged between the first control line CSL1 and the second control line CSL2.

When viewed on the plane (e.g., in a plan view), the pads PD may be arranged adjacent to the lower end of the second area AA2. The data driver DDV, the power line PL, the first control line CSL1, and the second control line CSL2 may be connected to the pads PD.

The data lines DL1 to DLn may be connected to the corresponding pads PD via the data driver DDV. For example, the data lines DL1 to DLn may be connected to the data driver DDV, and the data driver DDV may be connected to the corresponding pads PD for each of the data lines DL1 to DLn.

In one or more embodiments, a printed circuit board may be connected to the pads PD, and a timing controller and a voltage generator may be arranged on the printed circuit board. The timing controller may be manufactured in an integrated circuit chip and mounted on the printed circuit board. The timing controller and the voltage generator may be connected to the pads PD through the printed circuit board.

The timing controller may control operations of the scan driver SDV, the data driver DDV, and the emission driver EDV. The timing controller may generate a scan control signal, a data control signal, and an emission control signal in response to control signals received from outside. The voltage generator may generate a driving voltage.

The scan control signal may be provided to the scan driver SDV via the first control line CSL1. The emission control signal may be provided to the emission driver EDV via the second control line CSL2. The data control signal may be provided to the data driver DDV. The timing controller may receive image signals from outside, convert the data format of the image signals to match the interface specifications of the data driver DDV, and provide them to the data driver DDV.

The scan driver SDV may generate a plurality of scan signals in response to the scan control signal. The scan signals may be applied to the pixels PX through the scan lines SL1 to SLm. The scan signals may be sequentially applied to the pixels PX.

The data driver DDV may generate a plurality of data voltages corresponding to image signals in response to the data control signal. The data voltages may be applied to the pixels PX through the data lines DL1 to DLn. The emission driver EDV may generate a plurality of emission signals in response to the emission control signal. The emission signals may be applied to the pixels PX through the emission lines EL1 to ELm.

The pixels PX may receive the data voltages in response to the scan signals. The pixels PX may be to emit light with a brightness corresponding to the data voltages in response to the emission signals, thereby displaying an image. An emission time of the pixels PX may be controlled by the emission signals. Each pixel PX may include transistors, capacitors, and a light-emitting element connected to the transistors and the capacitors. Each of the transistors may include a semiconductor pattern. The semiconductor pattern may include polysilicon, amorphous silicon, and/or metal oxides. The semiconductor pattern may be doped with N-type (kind) dopants or P-type (kind) dopants. The semiconductor pattern may include high-doping regions and low-doping regions. The high-doping region may have a conductivity greater than that of the low-doping region and, substantially, the high-doping region may serve as source and drain electrodes of the transistor. The low-doping region may correspond to an active (or channel) of the transistor.

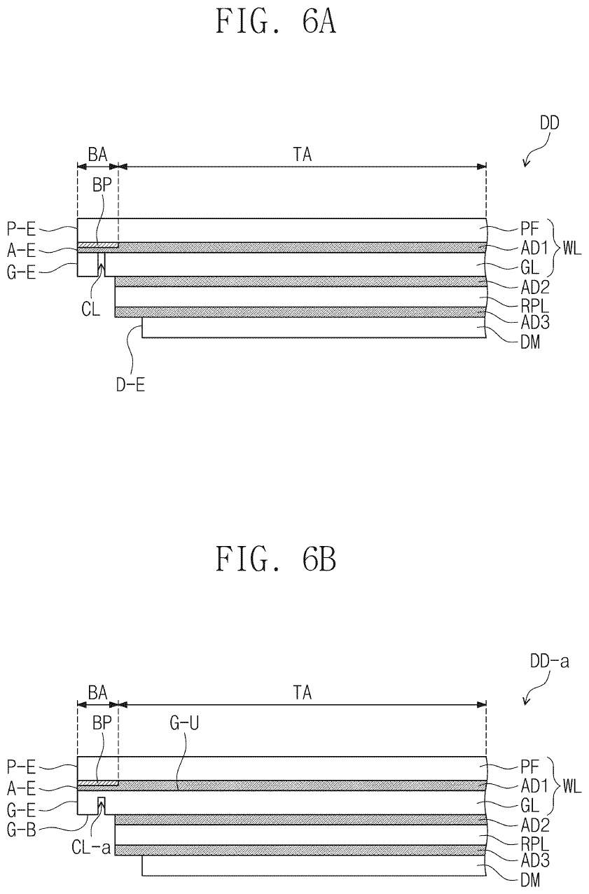

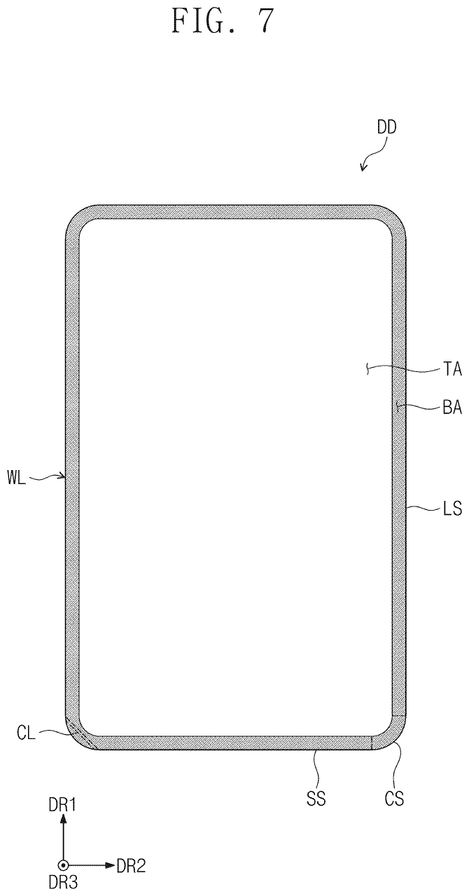

FIG. 6A is a cross-sectional view of a display device according to one or more embodiments of the present disclosure. FIG. 6B is a cross-sectional view of the display device according to one or more embodiments of the present disclosure. The same or similar reference numerals are used for components that are substantially identical or similar to those described in FIG. 3, and thus redundant explanations may not be provided. FIG. 7 is a plan view of a display device according to one or more embodiments of the present disclosure.

Referring to FIG. 6A, the display device DD may include a window WL, an optical layer RPL, and a display module DM. The window WL may include a protective layer PF, a first adhesive layer AD1 (an adhesive layer of claim), and a base substrate GL. The protective layer PF may be coupled to the base substrate GL through the first adhesive layer AD1. The window WL may be coupled to the optical layer PRL through a second adhesive layer AD2. The optical layer RPL may be coupled to the display module DM through a third adhesive layer AD3. According to one or more embodiments, the optical layer RPL and the second adhesive layer AD2 may not be provided. Here, the display module DM may be arranged below the window WL.

According to one or more embodiments of the present disclosure, a cutting line CL may be defined in the base substrate GL. The cutting line CL may overlap a light blocking pattern BP. The cutting line CL may be defined by a hole (or groove) passing through (e.g., passing entirely through) the base substrate GL. Accordingly, the first adhesive AD1 that overlaps the cutting line CL may be exposed to the outside through the cutting line CL. Because the cutting line CL according to one or more embodiments of the present disclosure is arranged below the light blocking pattern BP having a color, if (e.g., when) the user looks at the window, the cutting line CL may not be visible from the outside.

According to one or more embodiments, before the repair process is carried out, a side surface P-E of the protective layer PF, a side surface A-E of the first adhesive layer AD1, and a side surface G-E of the base substrate GL, which are included the window WL, may be aligned along the third direction DR3. Also, the side surface D-E of the display module DM may be arranged inward relative to the side surfaces P-E, A-E, and G-E included in the window WL.

The cutting line CL may serve as a guide to easily remove the first adhesive layer AD1 and the protective layer PF from the base substrate GL in the process for repairing the window, which will be described in more detail later. A more detailed explanation of this will be provided below.

Referring to FIG. 6B, a display device DD-a according to one or more embodiments may include a window WL, an optical layer RPL, and a display module DM. The window WL may include a protective layer PF, a first adhesive layer AD1, and a base substrate GL.

According to the present embodiment(s), a cutting line CL-a may be defined in the base substrate GL. In such embodiments, the cutting line CL-a may overlap the light blocking pattern BP. The cutting line CL may be defined by the removal of at least a portion of the base substrate GL. For example, according to this these embodiments, the cutting line CL may be defined by removing a portion of the base substrate GL in a direction from a bottom surface G-B of the base substrate GL toward a top surface G-U of the base substrate GL. In other words, the cutting line CL may be a groove that passes only part of the way through (partially through) the base substrate GL in a direction from a bottom surface G-B of the base substrate GL toward a top surface G-U of the base substrate GL.

However, the present disclosure is not limited thereto, and in one or more embodiments, the cutting line may be defined by removing a portion of the substrate GL in a direction from the top surface G-U to the bottom surface G-B of the base substrate GL, and in such embodiments, the cutting line may be filled with the first adhesive layer AD1. In other words, the cutting line CL may be a groove that passes only part of the way through (partially through) the base substrate GL in a direction from the top surface G-U to the bottom surface G-B of the base substrate GL and the cutting line may be filled with the first adhesive layer AD1.

FIG. 7 illustrates a shape of the window WL of the display device DD when viewed on a plane (e.g., in a plan view). The window WL may have a transmission area TA and a bezel area BA defined therein. The transmission area TA may correspond to the first active areas F-AA and F-AAa described in at least FIGS. 1A to 2C, and the bezel area BA may correspond to the first non-active areas F-NAA and F-NAAa described in at least FIGS. 1A to 2C. A boundary between the transmission area TA and the bezel area BA may be defined by the light blocking pattern BP. The light blocking patter BP may be arranged along the edge of the window WL.

According to one or more embodiments, the window WL may be defined by long sides LS extending along the first direction DR1, short sides LS extending along the second direction DR2, and corners CS connected to each of the long and short sides.

In such embodiments, the cutting line CL-a may overlap the light blocking pattern BP. According to one or more embodiments, the cutting line CL may overlap any one of the corners CS. Although the cutting line CL overlaps a lower left corner CS of the window WL in FIG. 7, the cutting line CL is not limited thereto. The cutting line CL according to one or more embodiments may extend in an oblique direction with respect to the first and second directions DR1 and DR2.

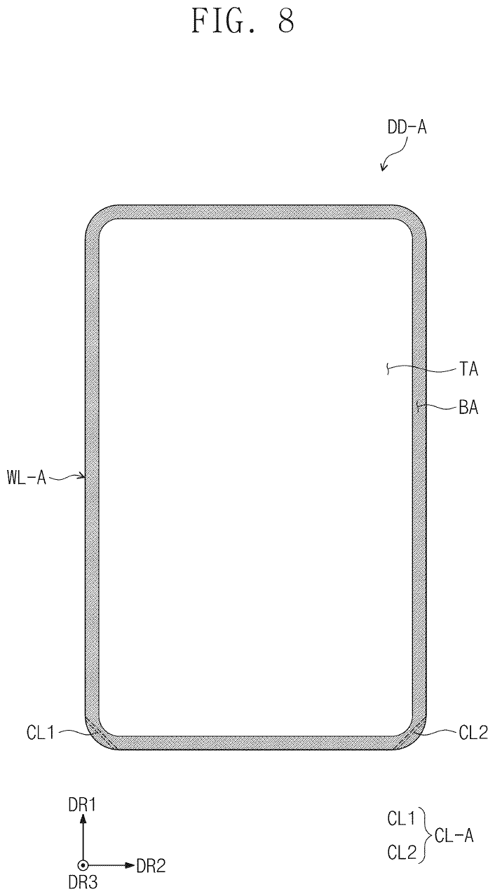

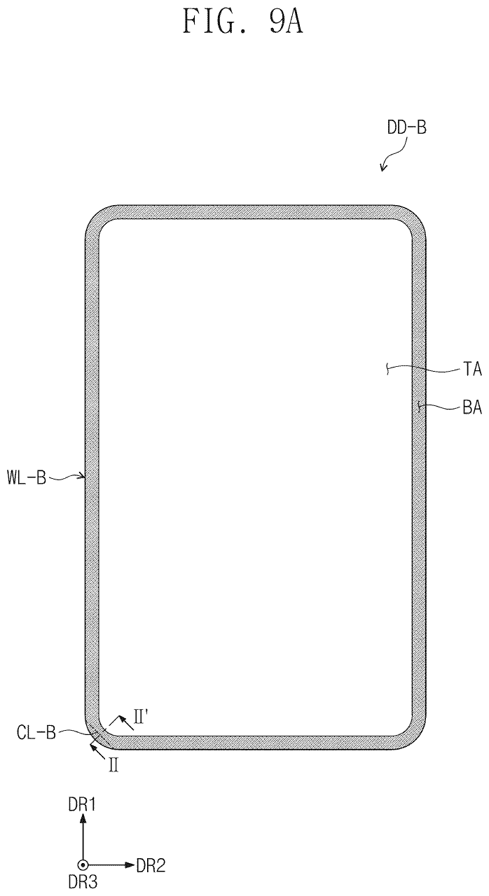

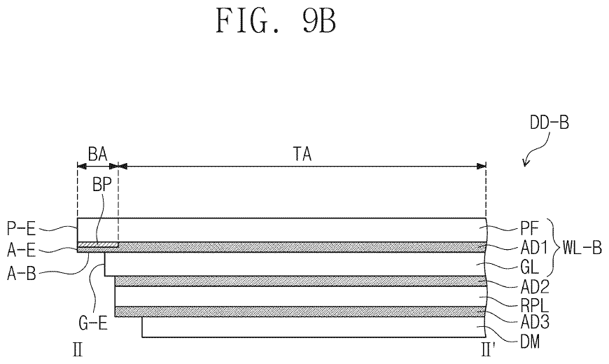

FIG. 8 is a plan view of a display device according to one or more embodiments of the present disclosure; FIG. 9A is a plan view of a display device according to one or more embodiments of the present disclosure; FIG. 9B is a cross-sectional view taken along the line II-II′ of FIG. 9A; and the same or similar reference numerals are used for the same or similar references as used in FIGS. 6A to 7, and thus redundant descriptions may not be provided.

Referring to FIG. 8, the display device DD-A may include a window WL-A. A cutting line CL-A may be defined in the window WL-A. The cutting line CL-A, according to the embodiments FIG. 8, may be provided in substantially the same way as any of the cutting lines described in FIGS. 6A and 6B.

The cutting line CL-A, according to such embodiments, may include a first cutting line CL1 and a second cutting line CL2 that are spaced and/or apart (e.g., spaced apart or separated) from each other. The first cutting line CL1 may be arranged at a lower left corner of the window WL-A, and the second cutting line CL2 may be arranged at a lower right corner of the window WL-A.

Referring to FIGS. 9A and 9B, a cutting line CL-B may be defined in the window WL-B included in a display device DD-B according to one or more embodiments of the present disclosure.

According to such embodiments, a base substrate GL may not be outside the cutting line CL-B. For example, a portion of the corner of the base substrate GL, which overlaps the light blocking pattern BP (see, e.g., FIG. 6A) may be cut off.

Accordingly, the side surface P-E of a protective layer PF and the side surface A-E of the first adhesive layer AD1 may be aligned with each other, and the aligned side surfaces P-E and A-E and the side surface G-E of the base substrate GL may be spaced and/or apart (e.g., spaced apart or separated) from each other. Therefore, a bottom surface A-B of the first adhesive layer AD1, which overlaps the light blocking pattern BP and is arranged on the outside of the cutting line CL-B, may be exposed from the base substrate GL.

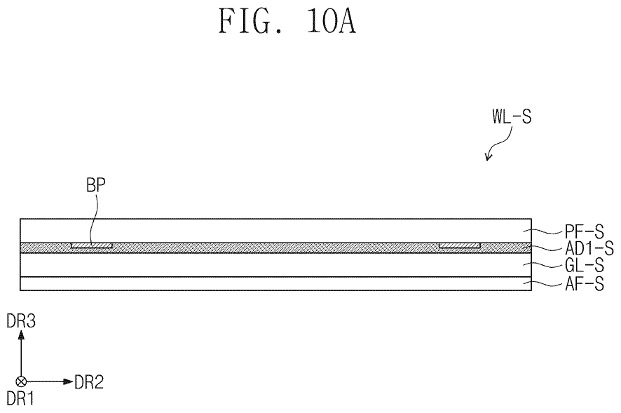

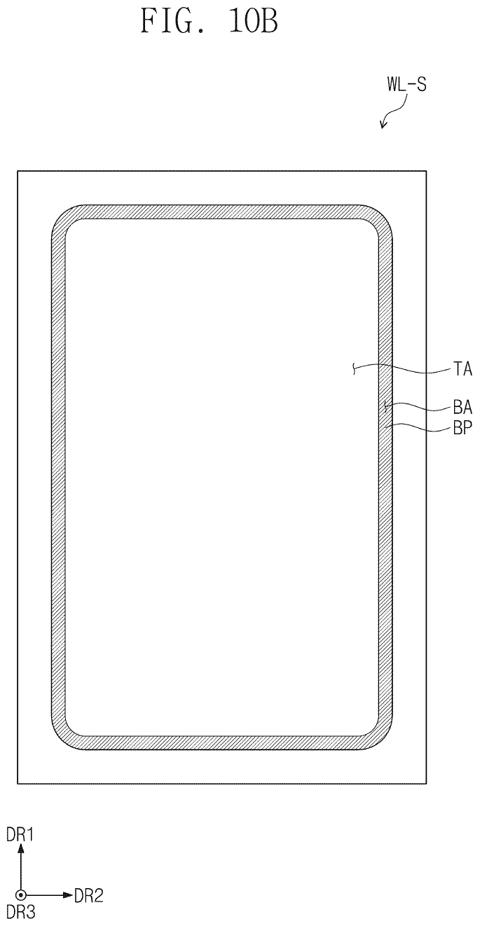

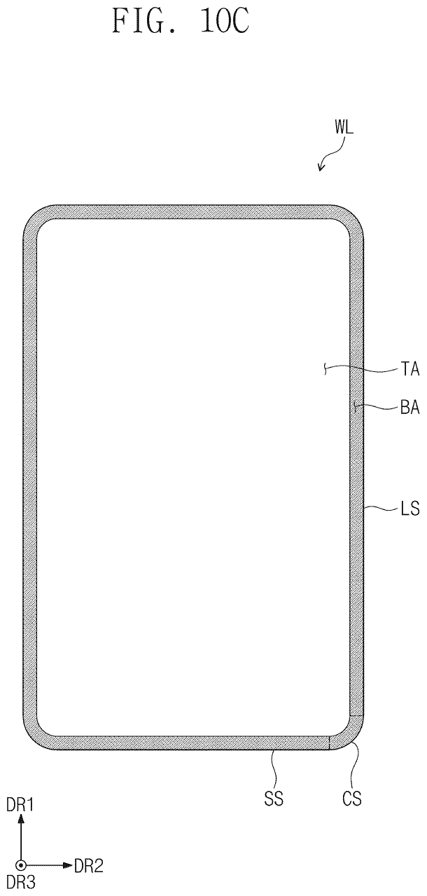

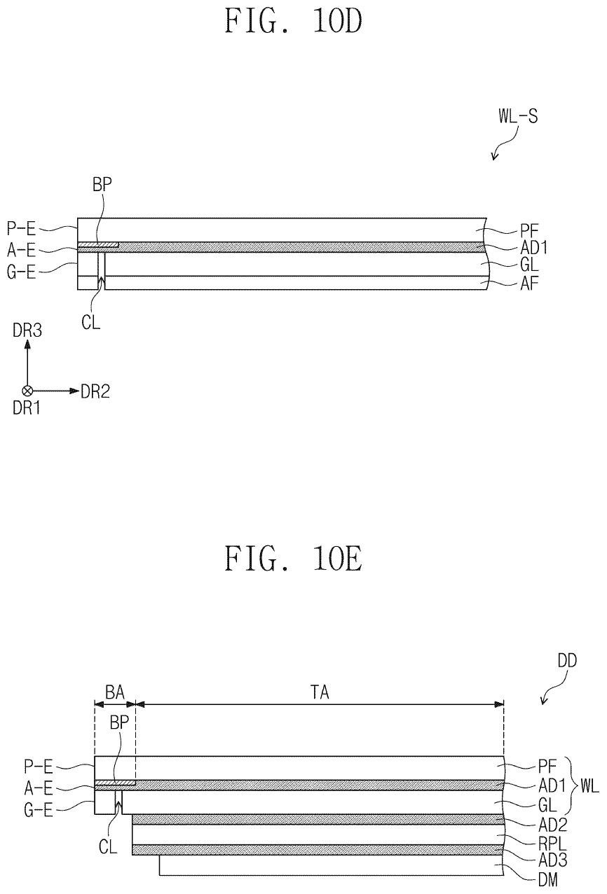

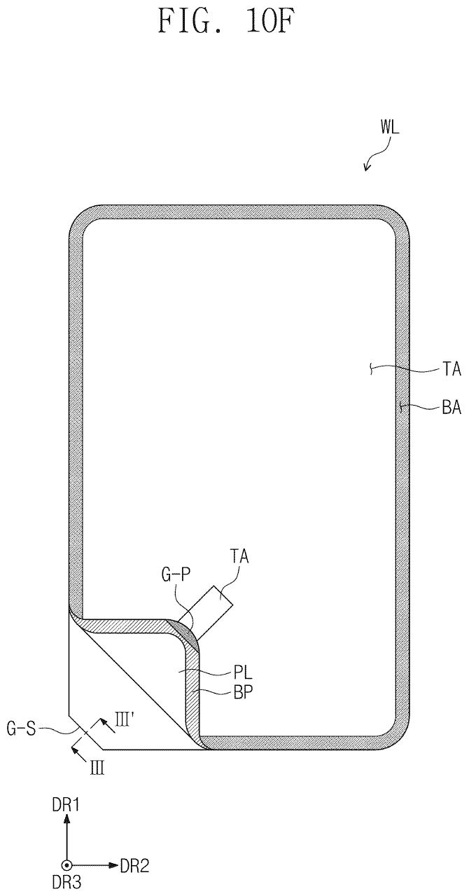

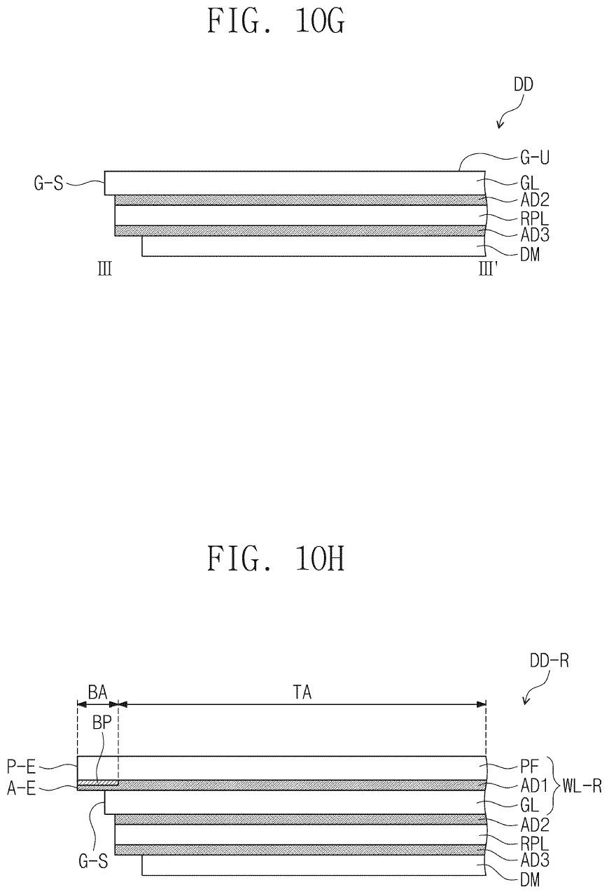

FIGS. 10A to 10H are views illustrating methods for repairing a display window according to one or more embodiments of the present disclosure. The same or similar reference numerals are used for the same or similar references as used in FIGS. 6A to 7, and thus redundant descriptions may not be provided. Hereinafter, a method for repairing a window according to one or more embodiments will be described with reference to FIGS. 10A to 10H.

The method for repairing a window according to one or more embodiments of the present disclosure includes coupling a base substrate, an adhesive layer, a light blocking pattern, and a protective layer to each other to form a window assembly, cutting the base substrate, the adhesive layer, and the protective layer along an outer portion of the light blocking pattern to form a window, forming a cutting line in a portion of the base substrate that overlaps with the light blocking pattern, coupling the window to a display module, and separating the base substrate from the adhesive layer, the light blocking pattern, and the protective layer by attaching a tape to the protective layer and using the cutting line as a boundary.

The method for repairing the window according to one or more embodiments may further include re-working in which a new adhesive layer, a new light blocking pattern and a new protective layer are coupled to the protective layer, after the separating of the base substrate from the adhesive, the light blocking pattern, and the protective layer. Also, the forming of the window may further include attaching a release film to a lower portion of the base substrate and include removing the release film before the coupling of the window to the display module.

Referring to FIGS. 10A and 10B, the method for repairing the window according to one or more embodiments may include a method for forming a window assembly WL-S (window).

The window assembly WL-S may include a mother base substrate GL-S, an adhesive layer AD-S, a protective layer PF-S, and a light blocking pattern BP. The light blocking pattern BP may be formed by a printing/coating process on a bottom surface of the protective layer PF-S and may be covered by the adhesive layer AD-S.

The method may further include the step (e.g., act or task) of attaching a release film AF-S according to one or more embodiments. The release film AF-S may be attached to the bottom surface of the base substrate GL-S. The release film AF-S may be removed from the base substrate GL-S in a subsequent process and may prevent or reduce the likelihood of (e.g., protect from) foreign substances adhering to the base substrate GL-S during the window repair process.

As shown in FIG. 10A, the mother base substrate GL-S, the adhesive layer AD-S, and the protective layer PF-S may have the same width on a plane (e.g., in a plan view). As shown in FIG. 10B, the window assembly WL-S may have a transmission area TA, which is an internal area of the light blocking pattern BP, and a bezel area BA, which overlaps the light blocking pattern BP, defined by the light blocking pattern BP.

Subsequently, referring to FIG. 10C, the method for repairing the window according to one or more embodiments may include a step (e.g., act or task) of forming a window WL. The window WL may be formed by concurrently (e.g., simultaneously) cutting the mother base substrate GL-S, the adhesive layer AD-S, and the protective layer PF-S from the window assembly WL-S. In such embodiments, a portion to be cut may be set using an outer portion of the light blocking pattern BP as a boundary.

As the base substrate GL-S, the adhesive layer AD1-S, and the protective layer PF-S are concurrently (e.g., simultaneously) cut by the mother base substrate, a side surface G-E of the base substrate GL-S, a side surface A-E of the adhesive layer AD1-S, and a side surface P-E of the protective layer PF-S may be aligned with each other.

According to one or more embodiments, the window WL may be defined by long sides LS extending along the first direction DR1, short sides LS extending along the second direction DR2, and corners CS connected to each of the long and short sides.

Subsequently, referring to FIG. 10D, the method for repairing the window according to one or more embodiments may include a step (e.g., act or task) of forming a cutting line CL. The cutting line CL may be formed at a corner CS of the base substrate GL that overlaps the light blocking pattern BP.

The cutting line CL according to this embodiment may be formed by passing through the base substrate GL starting from the release film AF. Accordingly, the first adhesive AD1 that overlaps the cutting line CL may be exposed to the outside through the cutting line CL. Because the cutting line CL according to the present disclosure is arranged below the colored light blocking pattern BP, if (e.g., when) the user looks at the window, the cutting line CL may not be visible from the outside.

The window repair method according to one or more embodiments may further include a step (e.g., act or task) of removing the release film AF. Accordingly, the release film AF may be removed from the bottom surface of the base substrate GL.

Subsequently, referring to FIG. 10E, the method may include a step (e.g., act or task) of coupling the window WL to the display module DM. An optical layer RPL may be attached to the display module DM. However, the present disclosure is not limited thereto, the optical layer RPL may not be provided, and the window WL may be directly coupled to the display module DM.

Subsequently, referring to FIGS. 10F and 10G, the method for repairing a window according to one or more embodiments may include a step (e.g., act or task) of separating the protective film PF and the adhesive layer AD1 from the base substrate GL. When a defect is found in the protective layer PF included in the window WL during the manufacturing process or during the user's use, a process of repairing may be performed to replace the protective layer PF.

In such embodiments, if (e.g., when) only the protective layer PF is removed and replaced with a new protective layer, the repair cost and time may be reduced compared to completely separating the display module DM from the window WL and replacing the entire window.

To easily separate the protective layer PF and the adhesive layer AD1 from the base substrate GL, a tape TA may be attached to a top surface of the protective layer PF. The tape TA may be attached to the corner where the cutting line CL is formed so that it overlaps the cutting line CL.

When the tape TA is pulled while held, the protective layer PF and the adhesive layer AD1 may be separated from the base substrate GL along the boundary of the cutting line CL. Here, a portion G-P of the base substrate GL that is arranged on an outer portion based on the cutting line CL may adhere to the adhesive layer AD1 and may be separated from the remaining portion of the base substrate GL together with the protective layer PF and the adhesive layer AD1.

Thus, as shown in FIG. 10G, the remaining portion of the base substrate GL may cover the display module DM, and the top surface G-U of the base substrate GL may be exposed.

Subsequently, referring to FIG. 10H, the method for repairing the window according to one or more embodiments may include a step (e.g., act or task) of re-working. The re-working may involve forming a repair window WL-R by combining a new adhesive layer AD1, a new light blocking pattern BP, and a new protective layer PF on the top surface of the base substrate GL. The new adhesive layer AD1, the new light blocking pattern BP, and the new protective layer PF may be coupled to the top surface G-U of the base substrate GL in a laminated state by a pre-process. Thus, the repair display device DD-R may include the repair window WL-R and the display module DM.

A side surface P-E of the new protective layer PF and a side surface A-S of the adhesive layer AD1 may not be aligned with a side surface G-S of the existing base substrate GL. The side surface G-S of the existing base substrate GL may have been formed as a result of the removal of a portion G-P from the existing base substrate GL.

According to one or more embodiments of the present disclosure, the protective layer PF, the adhesive layer AD1, and the base substrate GL, which are concurrently (e.g., simultaneously) cut and have aligned side surfaces, may be more easily separated along the cutting line CL. Additionally, because a portion of the base substrate GL remains on the display module DM, it may prevent or reduce the likelihood of (e.g., protect from) foreign substances entering or causing damage to the display module DM during the repair process.

According to one or more embodiments of the present disclosure, as the base substrate included in the window includes a cutting line, the protective layer and adhesive layer may be easily removed from the base substrate, thereby reducing the costs and time incurred in the window repair process.

Additionally, if (e.g., when) the protective layer and adhesive layer are removed from the base substrate, the base substrate remains on the display module, allowing the display module to be safely protected.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, electronic apparatus, device for manufacturing the display device, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a window comprising:
a protective layer;
a base substrate below the protective layer;
an adhesive layer between the protective layer and the base substrate; and
a light blocking pattern along an edge of the protective layer and between the protective layer and the adhesive layer; and
a display module below the window,
wherein a cutting line is defined in the base substrate, and
the cutting line overlaps the light blocking pattern.

2. The display device of claim 1, wherein the cutting line is a groove passing through the base substrate, and
the adhesive layer overlapping the cutting line is exposed through the cutting line.

3. The display device of claim 1, wherein the cutting line is a groove passing partially through the base substrate in a direction from a bottom surface of the base substrate toward a top surface of the base substrate.

4. The display device of claim 1, wherein the base substrate extends along first and second directions intersecting each other, and the cutting line extends in an oblique direction with respect to the first and second directions.

5. The display device of claim 1, wherein the base substrate has long sides and short sides, the long sides extending in directions that intersect the short sides, and corners at intersections of the long sides and the short sides, and the corners have a set or predetermined curvature.

6. The display device of claim 5, wherein the cutting line overlaps any one of the corners.

7. The display device of claim 6, wherein the cutting line comprises a plurality of cutting lines, and
each of the cutting lines overlaps one of the corners.

8. The display device of claim 1, wherein a side surface of the protective layer, a side surface of the adhesive layer, and a side surface of the base substrate are aligned with each other in a cross-section.

9. The display device of claim 1, wherein the cutting line is not visible from the outside in a plan view.

10. The display device of claim 1, wherein the base substrate comprises polyethylene terephthalate (PET).

11. The display device of claim 1, wherein the adhesive layer comprises at least one of a pressure-sensitive adhesive (PSA), an optically clear adhesive (OCA), or an optically clear resin (OCR).

12. The display device of claim 1, wherein the protective layer comprises at least one of a fingerprint-resistant coating agent, a hard coating agent, or an anti-static agent.

13. A display device comprising:
a window comprising:
a protective layer;
a base substrate below the protective layer;
an adhesive layer between the protective layer and the base substrate; and
a light blocking pattern along an edge of the protective layer and between the protective layer and the adhesive layer; and
a display module below the window,
wherein a groove is defined in the base substrate at corners of the base substrate overlapping the light blocking pattern.

14. A method for repairing a window, the method comprising:
coupling a base substrate, an adhesive layer, a light blocking pattern, and a protective layer to each other to form a window assembly;
cutting the base substrate, the adhesive layer, and the protective layer along an outer portion of the light blocking pattern to form the window;
forming a cutting line in a portion of the base substrate that overlaps the light blocking pattern;
coupling the window to a display module; and
separating the base substrate from the adhesive layer, the light blocking pattern, and the protective layer by attaching a tape to the protective layer and utilizing the cutting line as a boundary.

15. The method of claim 14, further comprising:
re-working the window by coupling a new adhesive layer, a new light blocking pattern and a new protective layer to the protective layer, after the separating of the base substrate from the adhesive layer, the light blocking pattern, and the protective layer.

16. The method of claim 15, wherein after the re-working of the window, side surfaces of the new adhesive layer and the protective layer protrude further outward than a side surface of the base substrate.

17. The method of claim 15, wherein in the separating of the base substrate from the adhesive layer, the light blocking pattern, and the protective layer, an outer portion of the base substrate with respect to the cutting line adheres to the adhesive layer and is removed from a remaining portion of the base substrate.

18. The method of claim 14, wherein in the forming of the cutting line, the cutting line passes through the base substrate to expose the adhesive layer.

19. The method of claim 14, wherein the forming of the window further comprises attaching a release film to a lower portion of the base substrate, and
in the forming of the cutting line, the release film is penetrated together with the base substrate.

20. The method of claim 19, further comprising:
removing the release film before the coupling of the window to the display module.

21. An electronic device comprising:
a display device comprising:
a window comprising:
a protective layer;
a base substrate below the protective layer;
an adhesive layer between the protective layer and the base substrate; and
a light blocking pattern along an edge of the protective layer and between the protective layer and the adhesive layer; and
a display module below the window,
wherein a cutting line is defined in the base substrate, and the cutting line overlaps the light blocking pattern.

22. The electronic device of claim 21, wherein the electronic device comprises a smartphone, a tablet, a car navigation system, a gaming console, or a wearable device.
